(19) United States
(12) Patent Application Publication
(10) Pub. No.: US 2022/0399195 A1
(43) Pub. Date: Dec. 15, 2022

(54) SPUTTER DEPOSITION

(71) Applicant: Dyson Technology Limited, Wiltshire (GB)

(72) Inventor: Michael Edward RENDALL, Newbury (GB)

(73) Assignee: Dyson Technology Limited, Wiltshire (GB)

(21) Appl. No.: 17/775,030

(22) PCT Filed: Nov. 10, 2020
(86) PCT No.: PCT/GB2020/052847

§ 371 Date: May 6, 2022

(30) Foreign Application Priority Data
Nov. 15, 2019 (GB) 1916621.4

(51) Int. Cl. H01J 37/34; H01J 37/32; C23C 14/35; C23C 14/56; C23C 14/04

(52) U.S. Cl. CPC H01J 37/3417; H01J 37/32357; H01J 37/345; H01J 37/3277; H01J 37/3435; C23C 14/352; C23C 14/351; C23C 14/562; C23C 14/04; H01J 2237/332; H01J 37/3211

(57) ABSTRACT

A sputter deposition apparatus including: a remote plasma generation arrangement arranged to provide a plasma for sputter deposition of target material within a sputter deposition zone; a confining arrangement arranged to provide a confining magnetic field to substantially confine the plasma in the sputter deposition zone a substrate provided within the sputter deposition zone; and one or more target support assemblies arranged to support one or more targets in the sputter deposition zone so as to provide for sputter deposition of the target material on the substrate. The confining arrangement confines the remote plasma to the target support assemblies such that in use there is deposited: target material as a first region on the substrate; target material as a second region on the substrate; and an intermediate region between the first and second region with no target material.

### TECHNICAL FIELD

The present invention relates to deposition, and more particularly to methods and apparatuses for sputter deposition of target material to a substrate.

### BACKGROUND

Deposition is a process by which target material is deposited on a substrate. An example of deposition is thin film deposition in which a thin layer (typically from around a nanometre or even a fraction of a nanometre up to several micrometres or even tens of micrometres) is deposited on a substrate, such as a silicon wafer or web. An example technique for thin film deposition is Physical Vapour Deposition (PVD), in which target material in a condensed phase is vaporised to produce a vapour, which vapour is then condensed onto the substrate surface. An example of PVD is sputter deposition, in which particles are ejected from the target as a result of bombardment by energetic particles, such as ions. In examples of sputter deposition, a sputter gas, such as an inert gas, such as argon, is introduced into a vacuum chamber at low pressure, and the sputter gas is ionised using energetic electrons to create a plasma. Bombardment of the target by ions of the plasma ejects target material which may then deposit on the substrate surface. Sputter deposition has advantages over other thin film deposition methods such as evaporation in that target materials may be deposited without the need to heat the target material, which may in turn reduce or prevent thermal damage to the substrate.

In some cases, it is desirable to deposit a pattern of material on a surface of a substrate rather than coating the entire surface. To create such a pattern, it is known to use a mask to protect areas of the surface which are to remain uncoated. In such cases, the material is deposited on the substrate itself in unmasked areas (which are not protected by the mask). However, the material is deposited on the mask (rather than the substrate) in masked areas.

Mask-based deposition can be wasteful due to discarding of material deposited on the mask. Furthermore, it may be necessary to halt deposition periodically to clean the mask. This can reduce deposition efficiency.

### SUMMARY

According to a first aspect of the present invention, there is provided a sputter deposition apparatus comprising: a remote plasma generation arrangement arranged to provide a plasma for sputter deposition of target material within a sputter deposition zone;

a confining arrangement arranged to provide a confining magnetic field to substantially confine the plasma in the sputter deposition zone

a substrate provided within the sputter deposition zone; and

one or more target support assemblies arranged to support one or more targets in the sputter deposition zone so as to provide for sputter deposition of the target material on the substrate;

wherein the confining arrangement confines the remote plasma to the target support assemblies such that in use there is deposited:
target material as a first region on the substrate;
target material as a second region on the substrate; and
an intermediate region between the first and second region with no target material.
   With such an apparatus, deposition of regions, such as stripes of material, for example to produce a particular pattern of regions or stripes on the substrate, may be performed more efficiently, as the pattern may be produced by the positioning of the one or more targets relative to the substrate rather than by using other elements, such as a mask. For example, such deposition may be performed continuously or with fewer breaks in operation compared to other processes, in which deposition may be ceased to clean components of the apparatus such as a mask. Furthermore, wastage of the material to be deposited may be reduced compared to other methods in which the material is deposited onto the substrate and subsequently removed, or in which the material is deposited onto a mask in areas of the substrate which are to remain free from the material.

In some examples, a conveyor system is arranged to convey the substrate from a first side of the sputter deposition zone to a second side of the sputter deposition zone; and the one or more target support assemblies comprise a first target support assembly arranged to support at least a first target and a second target support assembly arranged to support at least a second target. In such examples, there is a gap between the first target support assembly and the second target assembly which extends from the first side of the sputter deposition zone to the second side of the sputter deposition zone. This for example causes a corresponding gap in deposition to occur on a portion of the substrate. This allows a striped pattern to be produced on the substrate in a straightforward and efficient manner.

In these examples, the gap may be elongate along the conveyance direction, the first target support assembly may be elongate along the conveyance direction, and/or the second target support assembly may be elongate along the conveyance direction. This arrangement for example produces a more uniform pattern of deposited target material on the substrate than otherwise.

In some examples, the conveyor system is arranged to convey the substrate through the deposition zone from a first position thereof to a second position thereof; and the one or more target support assemblies are arranged to support a first target and a second target such that, at the first position, deposition onto the second portion is due to the first target and not the second target and, at the second position, deposition onto the second portion is due to the second target and not the first target. In this way, two stripes comprising material from two different targets can be deposited in a clean and efficient manner on the substrate.

In some examples, the one or more target support assemblies are arranged to support a first target and a second target such that the second target is offset from the first target within the sputter deposition zone and along an axis perpendicular to, but substantially within the plane of, the conveyance direction. This for example allows various different patterns of deposited target material to be provided on the substrate, depending on the degree of offset of the second target relative to the first target.

In these examples, in which the axis is a first axis, the one or more target support assemblies may be arranged to support the first target and the second target such that the second target is offset from the first target within the sputter deposition zone and along the conveyance direction. This for example provides further flexibility for the deposition of stripes of material on the substrate, according to a desired pattern.

In some examples, the one or more target support assemblies are arranged to support the first target and the second target such that at least one of the first target and the second target are at an oblique angle with respect to the conveyance direction. This arrangement provides yet further flexibility for deposition of target material. For example, a portion of the substrate may pass over part of one of the targets and then part of the other one of the targets, which may cause a combination of material of the first and second targets to be deposited, e.g. as a stripe of mixed material on the substrate.

In some examples, the sputter deposition apparatus comprises a first target magnetic element associated with the first target and a second target magnetic element associated with the second target. The first and second target magnetic elements may be considered to provide per-target biasing, allowing the magnetic field associated with the first and second targets to be controlled, e.g. to confine the plasma in a region adjacent to the first and second targets, respectively.

In these examples, the sputter deposition apparatus may further comprise a controller arranged to control: a first magnetic field provided by the first target magnetic element to control sputter deposition of material of the first target and/or a second magnetic field provided by the second target magnetic element to control sputter deposition of material of the second target. By controlling the magnetic field associated with different targets, deposition of material of the different targets may in turn be controlled, for example to deposit a greater quantity of material of one target than another.

In such cases, the one or more target support assemblies may be arranged to support the first target between the first target magnetic element and the conveyor system, and/or support the second target between the second target magnetic element and the conveyor system. With this arrangement, per-target biasing may be provided without the magnetic elements becoming contaminated due to contact with the plasma or with target material ejected from the targets during sputter deposition.

The material of the first target may be different from the material of the second target. This provides further flexibility for the use of the sputter deposition apparatus to produce various different deposition patterns on a substrate.

The plasma generation apparatus may comprise one or more elongate antennae, elongate along the conveyance direction. This for example allows a plasma to be generated which fills a sufficient extent of the sputter deposition zone to provide for deposition of a desired pattern of target material on the substrate.

In in such examples, the conveyor system may be arranged to convey the substrate along a curved path and the one or more elongate antennae may be curved in the same direction as a curvature of the curved path. This for example improves the uniformity of the target material deposited on the substrate, as the plasma density may also be more uniform between the substrate and the target support assemblies.

The sputter deposition apparatus may comprise a confining arrangement arranged to provide a confining magnetic field to substantially confine plasma in the sputter deposition zone to provide for sputter deposition of the target material, wherein the confining arrangement comprises at least one confining magnetic element that is elongate along the conveyance direction. This improves the efficiency of the deposition process, and reduces loss of the plasma due to leakage or other movement of the plasma beyond the sputter deposition zone.

In these examples, the confining arrangement may comprise a further at least one confining magnetic element that is elongate in a direction substantially perpendicular to the conveyance direction. This further improves the efficiency of the deposition process, and improves confinement of the plasma within the sputter deposition zone.

The one or more target support assemblies may be arranged to support the one or more targets without an intervening element between the one or more targets and the substrate during conveyance of the substrate through the sputter deposition zone by the conveyor system. In this way, the sputter deposition apparatus may be used to deposit a pattern of target material on a substrate which includes a region of the substrate which is substantially free from the target material, without the use of intervening elements such as masks. The efficiency of the deposition may therefore be improved.

The conveyor system may comprise a roller arranged to convey the substrate in the conveyance direction, wherein the conveyance direction is substantially perpendicular to an axis of rotation of the roller. In this way, the sputter deposition apparatus may form part of a roll-to-roll deposition system, which is for example more efficient than a batch process.

The conveyor system may comprise a curved member, and the one or more target support assemblies are arranged to support the one or more targets to substantially conform to a curvature of at least part of the curved member. This may increase the uniformity of the target material deposited on the substrate, as the distance between the targets and the substrate, as it is conveyed by the conveyor system, may be more uniform.

A surface of at least one of the one or more targets facing the conveyor system may be curved. This may similarly increase the uniformity of the target material deposited on the substrate.

According to a second aspect of the present invention, there is provided a method of sputter deposition of target material on a substrate, the method comprising: providing plasma within a sputter deposition zone; and conveying the substrate through the sputter deposition zone in a conveyance direction such that a position of one or more targets relative to the sputter deposition zone provides for sputter deposition of the target material on the substrate is such that, as the substrate is conveyed through the sputter deposition zone, there is deposited: first stripe on a first portion of the substrate; and a second stripe on a second portion of the substrate, wherein the first stripe comprises at least one of: a different density of the target material or a different composition of the target material than the second stripe. As described with reference to the first aspect, this allows deposition of stripes of material on a substrate to be performed more efficiently

Conveying the substrate may comprise conveying the first portion of the substrate within a first region of the sputter deposition zone which substantially overlaps a first target; conveying the second portion of the substrate within a second region of the sputter deposition zone which substantially overlaps a gap between the first target and a second target; and conveying a third portion of the substrate within a third region of the sputter deposition zone which substantially overlaps the second target. This allows a striped pattern to be produced on the substrate in a straightforward and efficient manner.

The method may comprise sputter depositing a material of the first target as the first stripe on the first portion of the substrate and sputter depositing a material of the second target as a third stripe on the second portion of the substrate, wherein the second stripe at least one of: comprises a lower density of the material of the first target than within the first stripe and a lower density of the material of the second target than within the third stripe; or is substantially free from the material of the first target and the material of the second target.

Conveying the substrate may comprise: conveying the first portion of the substrate within a first region of the sputter deposition zone which substantially overlaps a first portion of a target with a first length along the conveyance direction; and conveying the second portion of the substrate within a second region of the sputter deposition zone which substantially overlaps a second portion of the target with a second length along the conveyance direction, wherein the first length is different from the second length. In this way, a different density of the target material can be deposited in the first and second portions of the substrate, for example according to a desired deposition pattern.

Conveying the substrate may comprise: conveying the second portion of the substrate within a first region of the sputter deposition zone which substantially overlaps a first target; and subsequently, conveying the second portion of the substrate within a second region of the sputter deposition zone which substantially overlaps a second target. Such examples may include sputter depositing a combination of a material of the first target and a material of the second target as the second stripe on the second portion of the substrate. In this way, the combination of material of the first and second targets can be deposited, e.g. as a mixture, in a straightforward manner.

The first target may be elongate along the conveyance direction. In these examples, the method may comprise substantially confining a portion of the plasma such that the portion of the plasma is elongate along the conveyance direction. This for example improves the efficiency of the deposition process, by increasing an area of contact between the plasma and the first target.

In examples, the method comprises, during conveying the substrate, generating a first magnetic field associated with the first target and a second magnetic field associated with the second target, wherein the first magnetic field is different from the second magnetic field. By controlling the magnetic field associated with different targets, deposition of material of the different targets may in turn be controlled, for example to deposit a greater quantity of material of one target than another.

Further features will become apparent from the following description, given by way of example only, which is made with reference to the accompanying drawings.

### BRIEF DESCRIPTION OF THE DRAWINGS

FIG. 1 is a schematic diagram that illustrates a cross-section of an apparatus according to an example;

FIG. 2 is a schematic diagram that illustrates a plan view of a portion of the example apparatus of FIG. 1;

FIG. 3 is a schematic diagram that illustrates a view of a portion of the example apparatus of FIGS. 1 and 2;

FIG. 4 is a schematic diagram that illustrates a plan view of a further portion of the example apparatus of FIGS. 1 to 3;

FIG. 5 is a schematic diagram that illustrates a plan view of a portion of an apparatus according to a further example;

FIG. 6 is a schematic diagram that illustrates a plan view of a further portion of the example apparatus of FIG. 5;

FIG. 7 is a schematic diagram that illustrates a plan view of a portion of an apparatus according to a still further example;

FIG. 8 is a schematic diagram that illustrates a plan view of a further portion of the example apparatus of FIG. 7;

FIG. 9 is a schematic diagram that illustrates a plan view of a portion of an apparatus according to a yet further example;

FIG. 10 is a schematic diagram that illustrates a plan view of a further portion of the example apparatus of FIG. 9;

FIG. 11 is a schematic diagram that illustrates a cross-section of an apparatus according to a further example; and

FIG. 12 is a schematic diagram that illustrates a plan view of a portion of the example apparatus of FIG. 11.

### DETAILED DESCRIPTION

Details of apparatuses and methods according to examples will become apparent from the following description, with reference to the Figures. In this description, for the purpose of explanation, numerous specific details of certain examples are set forth. Reference in the specification to “an example” or similar language means that a particular feature, structure, or characteristic described in connection with the example is included in at least that one example, but not necessarily in other examples. It should further be noted that certain examples are described schematically with certain features omitted and/or necessarily simplified for ease of explanation and understanding of the concepts underlying the examples.

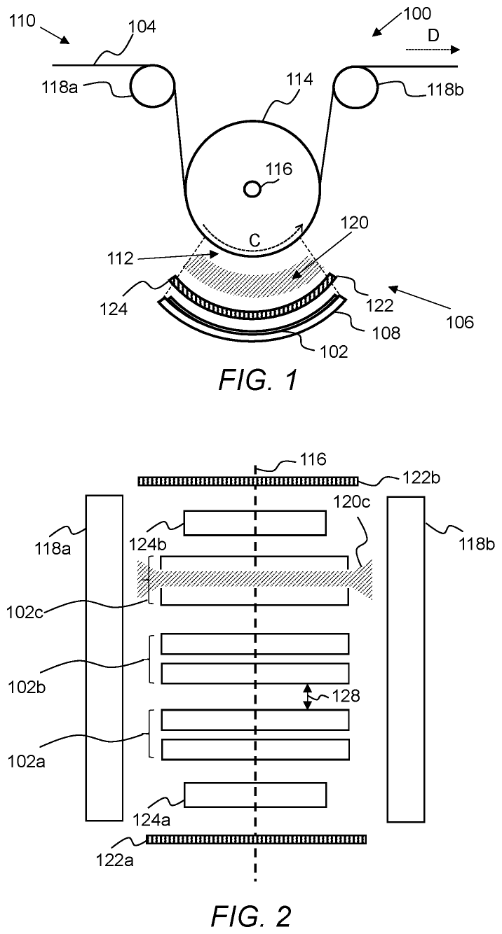

Referring to FIGS. 1 to 4, an example apparatus 100 for sputter deposition of target material 102 to a substrate 104 is illustrated schematically. Such an apparatus 100 may be referred to as a sputter deposition apparatus.

The apparatus 100 may be used for plasma-based sputter deposition for a wide number of industrial applications, such as those which have utility for the deposition of thin films, such as in the production of optical coatings, magnetic recording media, electronic semiconductor devices, LEDs, energy generation devices such as thin-film solar cells, and energy storage devices such as thin-film batteries. Therefore, while the context of the present disclosure may in some cases relate to the production of energy storage devices or portions thereof, it will be appreciated that the apparatus 100 and method described herein are not limited to the production thereof.

Although not shown in the Figures for clarity, it is to be appreciated that the apparatus 100 may be provided within a housing, which in use may be evacuated to a low pressure suitable for sputter deposition, for example 3×10⁻³ torr. For example, the housing may be evacuated by a pumping system (not shown) to a suitable pressure (for example less than 1×10⁻⁵ torr), and in use a process or sputter gas, such as argon or nitrogen, may be introduced into the housing using a gas feed system (not shown) to an extent such that a pressure suitable for sputter deposition is achieved (for example 3×10⁻³ torr).

Returning to the example illustrated in FIGS. 1 to 4, in broad overview, the apparatus 100 includes a plasma generation arrangement 106, one or more target support assemblies 108 (which may be referred to as a target support system), and a conveyor system 110.

The conveyor system 110 is arranged to convey the substrate 104 through a sputter deposition zone 112. The sputter deposition zone 112 is defined between the target support assemblies 108 and the conveyor system 110. The sputter deposition zone 104 may be taken as the region between the conveyor system 110 and the target support assemblies 108 in which sputter deposition from the target material 102 onto the substrate 104 occurs in use. The sputter deposition zone 112 of FIG. 1 is delimited by dashed lines to the left and right, by the target support assemblies 108 to the bottom and by the conveyor system 110 to the top. However, this is merely an example.

In this case, the substrate 104 is a web of substrate, although in other cases the substrate may be of a different form. A web of substrate for example refers to a flexible or otherwise bendable or pliable substrate. Such a substrate may be sufficiently flexible to enable bending of the substrate around rollers, for example as part of a roll-to-roll feeding system. In the example of FIGS. 1 to 4, the substrate 104 is conveyed by the conveyor system 110 along a curved path, which is indicated by the arrow C in FIG. 1. In other cases, though, the substrate may be relatively rigid or inflexible. In such cases, the substrate may be conveyed by the conveyor system without bending the substrate or without bending the substrate a substantial amount.

In some examples, the conveyor system 110 may include a curved member. In FIG. 1, the curved member is provided by a drum 114, which is for example a substantially cylindrical drum such as a roller, although in other examples, the curved member may be provided by a different component. The drum 114 may be considered to act as a substrate guide. The curved member may be arranged to rotate about an axis 116, for example provided by an axle. The axis 116 may also correspond to a longitudinal axis of the curved member. The conveyor system 110 may be arranged to feed the substrate 104 onto and from the drum 114 such that the substrate 104 is carried by at least part of a curved surface of the drum 114. In the example of FIG. 1, the conveyor system 110 includes a first roller 118a arranged to feed the substrate 104 onto the drum 114, and a second roller 118b arranged to feed the substrate 104 from the drum 114, after the substrate 104 has passed through the sputter deposition zone 112. The conveyor system 110 may be part of a “reel-to-reel” process arrangement, where the substrate 104 is fed from a first reel or bobbin of substrate material (such as a substrate web), passes through the apparatus 100, and is then fed onto a second reel or bobbin to form a loaded reel of processed substrate web.

The conveyor system 110 conveys the substrate 104 in a conveyance direction, indicated by the arrow D in FIG. 1. The conveyance direction D may be considered to correspond to the general direction of motion of the substrate 104 through the apparatus 100. For example, the conveyance direction D may be taken as the direction between a portion of the substrate 104 as it enters the apparatus 100 and a portion of the substrate 104 as it exits the apparatus 100. Where the conveyor system 110 includes a roller (such as the drum 114), the conveyance direction D may correspond to a direction of rotation of the roller, which may be taken at a tangent to an uppermost point of the roller. In such cases, the conveyor system 110 may be arranged to convey the substrate 104 in a conveyance direction D which is substantially perpendicular to an axis 116 of rotation of the roller (in this case, the drum 114). A direction may be considered substantially perpendicular to an axis where the direction is perpendicular to the axis, perpendicular to the axis within measurement tolerances, or within a few degrees, such as within 5 or 10 degrees. The conveyance direction D in FIG. 1 is a horizontal direction, although this is merely an example.

In some examples, the substrate 104 may be or include silicon or a polymer. In some examples, for example for the production of an energy storage device, the substrate 104 may be or include nickel foil, but it will be appreciated that any suitable metal could be used instead of nickel, such as aluminium, copper or steel, or a metallised material including metallised plastics such as aluminium on polyethylene terephthalate (PET).

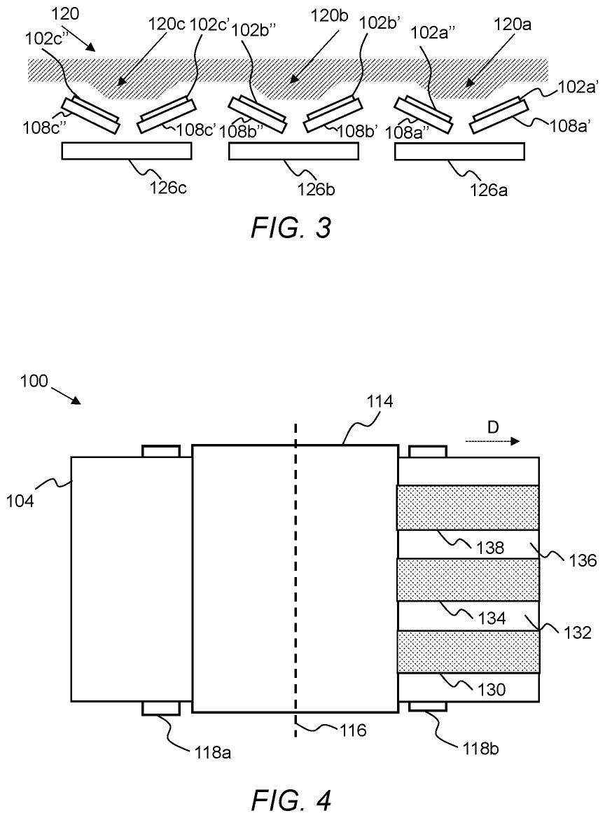

The one or more target support assemblies 108 are arranged to support the target material 102, for example by supporting one or more targets comprising the target material 102. Each of the one or more target support assemblies 108 may support one or more of the targets. In FIG. 1, only one of the target support assemblies 108 is visible, however, FIGS. 2 and 3 show the target support assemblies 108 more fully. In some examples, the target support assemblies 108 may include at least one plate or other support structure that supports or holds the target material 102 in place during sputter deposition.

The target material 102 may be a material on the basis of which the sputter deposition onto the substrate 104 is to be performed. For example, the target material 102 may be or include material that is to be deposited onto the substrate 104 by sputter deposition. In some examples, for example for the production of an energy storage device, the target material 102 may be or include, or may be or include a precursor material for, a cathode layer of an energy storage device, such as a material which is suitable for storing Lithium ions, such as Lithium Cobalt Oxide, Lithium Iron Phosphate or alkali metal polysulphide salts. Additionally or alternatively, the target material 102 may be or include, or may be or include a precursor material for, an anode layer of an energy storage device, such as Lithium metal, Graphite, Silicon or Indium Tin Oxides. Additionally or alternatively, the target material 102 may be or include, or may be or include a precursor material for, an electrolyte layer of an energy storage device, such as material which is ionically conductive, but which is also an electrical insulator, such as lithium phosphorous oxynitride (LiPON). For example, the target material 102 may be or include LiPO as a precursor material for the deposition of LiPON onto the substrate 104, for example via reaction with Nitrogen gas in the sputter deposition zone 112.

The target support assemblies 108 in examples herein are arranged to support the one or more targets in a position relative to the sputter deposition zone 112 so as to provide for sputter deposition of the target material 102 on the substrate 104 such that, as the substrate 104 is conveyed through the sputter deposition zone 112 in use, there is deposited a first region (shown as, and referred to as a stripe) on a first portion of the substrate 104 and a second region (shown as, and referred to as a stripe) on a second portion of the substrate 104, wherein the first stripe includes at least one of a different density of the target material 102 or a different composition of the target material 102 than the second stripe. Hence, in such examples, it is the positioning of the target material 102 relative to the substrate 104 (as it is conveyed by the conveyor system 110) which leads to the deposition of the first stripe and the second stripe rather than other features of the sputter deposition apparatus 100, such as a mask. In this way, deposition of stripes of material, for example to produce a particular pattern of stripes on the substrate 104, may be performed more efficiently. For example, such deposition may be performed continuously or with fewer breaks in operation compared to other processes, in which deposition may be ceased to clean components of the apparatus such as a mask. Furthermore, wastage of the material to be deposited may be reduced compared to other methods in which the material is deposited onto the substrate and subsequently removed, or in which the material is deposited onto a mask in areas of the substrate which are to remain free from the material. Example arrangements of the target support assemblies 108, and the deposition patterns produced with such arrangements, are discussed in more detail with reference to FIGS. 2 to 10.

In some examples, such as those illustrated, the apparatus may include a plasma generation arrangement 106. The plasma generation arrangement 106 is arranged to provide plasma 120 for sputter deposition of the target material 102 supported by the target support assemblies 108 within the sputter deposition zone 112.

In some examples, the plasma generation arrangement 106 may be disposed remotely of the conveyor system 110. For example, the plasma generation arrangement 106 may be disposed at a distance radially away from the conveyor system 110. As such, plasma 120 may be generated remotely from the conveyor system 110, and remotely from the sputter deposition zone 112.

In some examples, the plasma generation arrangement 106 may include one or more antennae 122 through which appropriate radio frequency power may be driven by a radio frequency power supply system so as to generate an inductively coupled plasma 120 from the process or sputter gas. In some examples, plasma 120 may be generated by driving a radio frequency current through the one or more antennae 122, for example at a frequency between 1 MHz and 1 GHz; a frequency between 1 MHz and 100 MHz; a frequency between 10 MHz and 40 MHz; or at a frequency of approximately 13.56 MHz or multiples thereof. The radio frequency power causes ionisation of the process or sputter gas to produce plasma 120.

One or more antennae of the plasma generation arrangement 106 may be elongate antennae 122, which may be elongate along a conveyance direction D in which the conveyor system 110 is arranged to convey the substrate 104. In such cases, the elongate antennae may extend in a direction perpendicular to the axis 115 of rotation of the drum 114. The axis 116 of rotation of the drum 114 for example passes through an origin of a radius of curvature of the curved drum 114, and in FIG. 1 corresponds to the axle on which the drum 114 is mounted. In such cases, the antennae need not exactly or precise follow the conveyance direction D or a direction perpendicular to the axis of rotation of the drum 114 for the antennae to be elongate in these directions. For example, an antenna 122 may be considered elongate along a given direction where a length of the antenna 122 taken parallel to the given direction is larger than a width of the antenna 122 taken perpendicular to the given direction.

While in some cases, the antennae may be linear in shape, in other cases the antennae may be curved. For example, where the conveyor system 110 is arranged to convey the substrate 104 along a curved path, the one or more elongate antennae 122 may be curved in the same direction as a curvature of the curved path, for example as shown in FIG. 1. Such an antenna 122 may for example have a half-moon shape in cross-section. A curved antenna such as the antenna 122 of FIG. 1 may be parallel to but radially and axially offset from the curved path C, e.g. parallel to but radially and axially offset from the curved surface of the curved member, such as the drum 114, that guides the substrate along the curved path C. The curved antenna may be driven with radio frequency power to produce plasma 120 having a substantially curved shape.

In some examples, the plasma generation arrangement 106 comprises two antennae 122a, 122b for producing an inductively coupled plasma 120, as can be seen more clearly in FIG. 2. FIG. 2 shows FIG. 1 in plan view, with the substrate 104 and elements of the conveyor system 110 omitted for clarity. The antennae 122a, 122b may extend substantially parallel to one another and may be disposed laterally from one another, for example at opposite sides of the sputter deposition zone. In examples herein, two elements may be considered substantially parallel to each other where they are parallel to each other, parallel to each other within manufacturing or measurement tolerances, or parallel to each other within a few degrees, such as within 5 degrees or 10 degrees. Such an arrangement may allow for a precise generation of an elongate region of plasma 120 between the two antennae 122a, 122b, which may in turn help provide for precise confinement of the generated plasma 120 within the sputter deposition zone 112. In some examples, the antennae 122a, 122b may be similar in length to the target support assemblies 108. The antennae 122a, 122b may be separated from each other by a distance which is similar to a width of a substrate guide for guiding the substrate 104 through the deposition zone 112. In FIG. 1, the substrate guide is provided by the drum 114. In this way, a separation between the antennae 122a, 122b may be similar to a width of the web of substrate 104 conveyed by the conveyor system 110. The antennae 122a, 122b may provide for plasma 120 to be generated across a region having a length corresponding to the length of the substrate guide (and hence corresponding to the width of the web of substrate 104), and hence may allow for plasma 120 to be available evenly or uniformly across the width of the sputter deposition zone 112. This may in turn help provide for even or uniform sputter deposition.

The sputter deposition apparatus 100 in examples such as that of FIG. 1 may further include a confining arrangement 124. The confining arrangement 124 may include one or more magnetic elements arranged to provide a confining magnetic field to substantially confine plasma 120 (e.g. the plasma generated by the plasma generation arrangement 106) in the sputter deposition zone 112, in order to provide for sputter deposition of target material 108 to the web of substrate 104 in use. The plasma 120 may be considered substantially confined in the sputter deposition zone 112 for example where leakage or other movement of the plasma 120 to regions outside the sputter deposition zone 112 is relatively small, e.g. negligible or sufficiently small to continue with the sputter deposition process without significantly affecting the rate of sputter deposition. In some cases, the confining arrangement 124 includes at least one confining magnetic element that is elongate along the conveyance direction D. For example, the confining magnetic element may be elongate in a direction which is parallel to the conveyance direction D, parallel to the conveyance direction D within measurement tolerances, within a few degrees, such as within 5 degrees or 10 degrees, or such that a length of the confining magnetic element parallel to the conveyance direction D is greater than a width of the confining magnetic element perpendicular to the conveyance direction D.

In FIGS. 1 and 2, the confining arrangement 124 includes two confining magnetic elements 124a, 124b which are parallel to but at a distance from the antennae 122 in a direction parallel to an axis of rotation of the drum 114. Hence, in FIG. 1, the confining magnetic elements 124a, 124b are located behind a first antenna 122a, and between the first antenna 122a and a second antenna 122b. The position of the confining magnetic elements 124a, 124b is shown more clearly in FIG. 2.

The confining magnetic field generated by the confining arrangement 124 may be characterised by magnetic field lines arranged to, at least in the sputter deposition zone 112, substantially follow a curve of the curved path C so as to confine the plasma 120 in a curved region following the curve of the curved path C. In some examples, the magnetic field lines characterising the confining magnetic field may be arranged such that an imaginary line, extending perpendicularly to each magnetic field line and connecting the magnetic field lines, is curved so as to, at least in the deposition zone, substantially follow the curve of the curved path C.

In the example of FIG. 1, the confining arrangement 124 is arranged to provide a confining magnetic field comprising confining magnetic field lines which are each themselves substantially straight and extend in a direction parallel to an axis of rotation of the drum 114 but are arranged such that an imaginary line, extending perpendicularly to each magnetic field line and connecting the magnetic field lines, is curved so as to, at least in the sputter deposition zone 112, substantially follow the curve of the curved path C.

In some examples, one or more of the confining magnetic elements 124a, 124b may be an electromagnet. The sputter deposition apparatus 100 may comprise a controller (not shown) arranged to control a strength of the magnetic field provided by one or more of the electromagnets. This may allow for the arrangement of the magnetic field lines characterising the confining magnetic field to be controlled. This may allow for adjustment of the plasma density at the substrate 104 and/or the target material 102 and hence for improved control over the sputter deposition. This may allow for improved flexibility in the operation of the sputter deposition apparatus 100.

At least one of the confining magnetic elements 124a, 124b may comprise a solenoid. A solenoid may have an opening through which plasma 120 is guided in use. The opening may be curved and elongate in a direction substantially perpendicular to the longitudinal axis (rotational axis) of the curved member (the axis of rotation of the drum 114 in FIG. 1). A curved solenoid such as this may substantially follow the curve of the curved path C, as shown in FIG. 1. For example, the curved solenoid may be parallel to but radially and axially offset from the curved surface of the curved member (which in FIG. 1 is the drum 114). This is shown in FIG. 2, which shows a first confining magnetic element 124a (which may be a curved solenoid) which is disposed intermediate of a first antenna 122a and the curved member. A second confining magnetic element 124b is arranged on an opposite side of the curved member to the first confining magnetic element 124a in the sense of FIG. 1. The second confining magnetic element 124b (which may also be a curved solenoid) is disposed between a second antenna 122b and the curved member. Curved solenoids such as this may provide a confining magnetic field in which the field lines are arranged such that an imaginary line, extending perpendicularly to each magnetic field line and connecting the magnetic field lines, is curved so as to, at least in the sputter deposition zone 112, substantially follow the curve of the curved path C.

Plasma 120 may be generated along the length of the antennae 122a, 122b, and the confining arrangement 124 may confine the plasma 120 within a region bound by the antennae 122a, 122b and the confining magnetic elements 124a, 124b. The plasma 120 may be confined by the confining magnetic elements 124a, 124b in the form of a curved sheet. In this case, the length of the curved sheet extends in a direction parallel to the longitudinal (rotational) axis of the curved member. The plasma 120, in the form of a curved sheet, may be confined by the magnetic field provided by the confining magnetic elements 124a, 124b around the curved member and so as to replicate the curve of the curved member (such as the curve of the drum 114 in FIG. 1). The thickness of the curved sheet of plasma may be substantially constant along the length and width of the curved sheet. The plasma in the form of a curved sheet may have a substantially uniform density, for example the density of the plasma in the form of a curved sheet may be substantially uniform in one or both of its length and width. The plasma being confined in the form of a curved sheet may allow for an increased area in which sputter deposition may be effected and hence for more efficient sputter deposition, and/or for a more uniform distribution of plasma density at the web of substrate 104, for example in both of a direction around the curved of the curved member, and across the width of the substrate 104. This may in turn allow for a more uniform sputter deposition onto the web of substrate 104, e.g. in a direction around the surface of the curved member and across the length of the curved member, which may improve the consistency of the processing of the substrate 104.

Confining the plasma 120 in the form of a curved sheet, for example a curved sheet having, at least in the sputter deposition zone 112, a substantially uniform density, may alternatively or additionally allow for a more uniform distribution of plasma density at the web of substrate 104, for example in both of a direction around the curve of the curved member 114, and over the length of the curved member 114. This may in turn allow for a more uniform sputter deposition onto the web of substrate 104, e.g. in a direction around the surface of the curved member and across the width of the substrate 104. The sputter deposition may therefore, in turn, be performed more consistently. This may, for example, improve the consistency of the processed substrate, and may for example, reduce the need for quality control. This may be as compared to, for example, magnetron type sputter deposition apparatuses where the magnetic field lines characterising the magnetic field produced thereby loop tightly into and out of a substrate, and hence do not allow to provide uniform distribution of plasma density at the substrate.

In some examples, the plasma 120 may, at least in the sputter deposition zone 112, be high density plasma. For example, the plasma 120 (in the form of a curved sheet or otherwise) may have, at least in the deposition zone 112, a density of 10¹¹ cm⁻³ or more, for example. Plasma 120 of high density in the deposition zone 112 may allow for effective and/or high rate sputter deposition.

In the example illustrated in FIG. 1, the target support assemblies 108 are substantially curved. In the example of FIG. 1, the target material 102 supported by the target support assemblies 108 are accordingly substantially curved. In this case, any one part of the curved target support assemblies 108 forms an obtuse angle with any other part of the curved target support assemblies 108 along the direction of the curve. In some examples, different parts of the target support assemblies 108 may support different target materials, for example to provide for a desired arrangement or composition of deposition to the web of substrate 104.

In some examples, the curved target support assemblies 108 may substantially follow the curve of the curved path C. For example, the curved target support assemblies 108 may substantially conform to or replicate the curved shape of the curved path C. For example, the curved target support assemblies 108 may have a curve that is substantially parallel to but radially offset from the curved path. For example, the curve target support assemblies 108 may have a curve that has a common centre of curvature to the curved path C, but a different, in the illustrated examples larger, radius of curvature to the curved path C. Accordingly, the curved target support assemblies 108 may in turn substantially follow the curve of the curved plasma 120 substantially confined around the curved member (the drum 114 of FIG. 1) in use. Put another way, in some examples, the plasma 120 may be substantially confined by the confining magnetic elements 124a, 124b of the confining arrangement to be located between the path C of the substrate 104 and the target support assemblies 108, and substantially follow the curve of both the curved path C and the curved target support assemblies 108. In other cases, though, one or more of the target support assemblies and/or the target(s) supported by the target support assemblies may be planar, e.g. non-curved.

It will be appreciated that the example target support assemblies 108 (and accordingly the target material 102 supported thereby) may extend substantially across an entire length of the curved member (such as the drum 114 of FIG. 1), e.g. in a direction parallel with the longitudinal axis of the drum 114. This may maximise the surface area of the web of substrate 104 carried by the drum 114 onto which target material 102 may be deposited. In FIG. 1, the target support assemblies 108 (and the target material 102 support thereby) extend parallel to a lower portion of the drum 114 corresponding to approximately a quarter of a diameter of the drum 114. In other examples, though, the target support assemblies 108 and/or the target material 102 may extend parallel to a greater extent of the drum 114. For example, the target support assemblies 108 and/or the target material 102 may extend further upwards and around the drum 114 of FIG. 1, for example so that the ends of at least one of the target support assemblies 108 are in line with or above the axle on which the drum 114 is mounted, in the sense of FIG. 1.

The plasma 120 may be substantially confined by the confining arrangement 124 to substantially follow the curve of both the curved path C and the curved target support assemblies 108. The area or volume between the curved path C and the curved target support assemblies 108 may accordingly be curved around the curved member. The sputter deposition zone 112 may therefore represent a curved volume in which sputter deposition of the target material 102 to the substrate 104 carried by the conveyor system 110 occurs in use. This may allow for an increase of the surface are of the web of substrate 104 carried by the conveyor system 110 present in the sputter deposition zone 112 at any one time. This in turn may allow for an increase in the surface area of the web of substrate 104 onto which target material 102 may be deposited in use. This in turn may allow for an increased area in which sputter deposition may be effected, but without substantially increasing the spatial footprint of the target support assemblies 108, and without altering the dimensions of components of the conveyor system 110, such as the drum 114. This may allow, for example, for the web of substrate 104 to be fed through a reel-to-reel type apparatus at a (still) faster rate for a given degree of deposition, and hence for more efficient sputter deposition, but also in a space efficient way.

Further features of the sputter deposition apparatus 100 of FIG. 1 are shown in FIG. 2, which shows the sputter deposition apparatus 100 of FIG. 1 in plan view, with the substrate 104, part of the conveyor system 110 and part of the plasma 120 omitted for clarity.

In the example of FIG. 2, the target support assemblies 108 are arranged to support a first target 102a using a first target support assembly, a second target 102b using a second target support assembly and a third target 102c using a third target support assembly. The first, second and third target support assemblies together form the target support assemblies 108 which are omitted from FIG. 2, for clarity, but which are shown in more detail in FIG. 3. However, in other examples, the target support assemblies may include more or fewer target support assemblies. In FIG. 2, the first, second and third target 102a, 102b, 102c comprise different materials, respectively. For example, the material of the first target may be different from the material of the second target. In other cases, though, the first, second and/or third targets may comprise some or all of the same material. In examples such as that of FIGS. 1 to 4, in which the target support assemblies 108 are arranged to support a plurality of targets, at least one of the targets may be smaller than otherwise. A smaller target may be easier to handle, store and/or transfer into the one or more target support assemblies than a larger target, for example in cases in which the target is to be stored in a vacuum environment.

As explained with reference to FIG. 1, the first, second and third targets 102a, 102b, 102c shown in FIG. 2 are each elongate along the conveyance direction D, which in this case is in a direction perpendicular to the axis 116 of rotation of the drum 114. The first, second and third targets 102a, 102b, 102c extend from a first side of the sputter deposition zone 112 (the left side of FIG. 1) to a second side of the sputter deposition 112 (the right side of FIG. 1), so as to provide for deposition of material of the first, second and third targets 102a, 102b, 102c on the substrate 104 using sputter deposition. In such cases, the first, second and third target support assemblies may also be elongate in the direction perpendicular to an axis 116 of rotation of the drum 114. For example, the first, second and third target support assemblies may extend from the first side of the sputter deposition zone 112 to the second side of the sputter deposition 112 so as to support the first, second and third targets 102a, 102b, 102c appropriately for deposition of the material of the first, second and third targets 102a, 102b, 102c on the substrate 104 within the sputter deposition zone 112.

In examples in which the conveyor system 110 includes a curved member (such as the drum 114), the target support assemblies (for example including target support assemblies such as the first, second and third target support assemblies shown in FIG. 3) may be arranged to support at least one of the targets to substantially conform to a curvature of at least part of the curved member. For example, the target support assemblies 108 may be arranged to support one or more of the targets to substantially conform to a curvature of at least part of the curved member. The target support assemblies may be considered to support at least one target to substantially conform to the curvature of at least part of the curved member where the at least one target for example replicates or otherwise follows the curvature of the at least part of the curved member. For example, the target support assemblies may support at least one target along a curved path that has a common centre of curvature with the curved member, but which has a different, for example larger, radius of curvature than that of the curved member. For example, the at least one target may be arranged along a curved path that is substantially parallel to but radially offset from the at least part of the curved member.

The at least one target may itself have a curved surface, which may substantially conform to the curvature of the at least part of the curved member. In some examples, at least one of: a first surface of the first target 102a facing the conveyor system is curved, a second surface of the second target 102b facing the conveyor system is curved, or a third surface of the third target 102c facing the conveyor system is curved. A surface may be considered curved where it deviates from a flat plane. For example, the target support assemblies 108 may be arranged to support at least one target with a surface which curves at least partly around a conveyor system 110 for conveying a substrate 104. Such an example is shown in FIG. 1. In FIG. 1, the respective surfaces of each of the targets follows a curved path that substantially conforms to, and may be considered to replicate, a curvature of part of at least part of the curved member (in this case, a lower portion of the drum 114). In other cases, though, at least one of the targets may not have a curved surface and may, instead, have a flat surface, which for example lies in a flat plane.

In other cases, instead of, or in addition to, having a curved surface, the target support assemblies 108 may be arranged to support a plurality of targets along the curvature of the at least part of the curved member, for example in an end-to-end fashion (although this need not be the case). In such cases, a surface of one of the targets may define a surface forming an obtuse angle with respect to a surface of another of the targets. The obtuse angle may be chosen such that the targets together are arranged so as to approximate the curve of the curved path C.

In other cases, the target support assemblies 108 may be arranged to support at least one target with a planar surface, rather than a curved surface. Alternatively or additionally, the target support assemblies 108 may be arranged to support at least one target in a plane, such as a plane parallel to the substrate 104 as it is fed into the sputter deposition apparatus 100 (which for example corresponds to the conveyance direction D), rather than to conform to a curvature of a curved member.

In the example of FIGS. 1 to 4, the first target support assembly includes first and second support portions 108a′, 108a″, as shown in FIG. 3. The first support portion 108a′ is arranged to support a first portion 102a′ of the material of the first target 102 and the second support portion 108a″ is arranged to support a second portion 102a″ of the material of the first target 102. In other examples, though, the first and second support portions 108a′ may support different target materials. The first target support assembly may include more or fewer support portions, each of which may support one or more targets. In this example, the first target 102a is discontinuous between the first and second support portions 108a′, 108a″. In other words, the first portion 102a′ of the first target 102a is disconnected from or otherwise separated or not in contact with the second portion 102a″ of the first target 102a. The first and second portions 102a′, 102a″ may nevertheless be considered to form part of the same, first target 102a for example where the first and second portions 102a′, 102a″ include the same material or where the first and second portions 102a′, 102a″ are supported by the same target support assembly and/or are associated with the same target magnetic element 126a (discussed further below). In other cases, the first target may be continuous such that a central portion of the first target overlaps a gap between the first and second support portions 108a′, 108a″.

The first and second support portions 108a′, 108a″ in this example are arranged at an angle with respect to each other. This is shown more clearly in FIG. 3, which shows the target support assemblies 108 of FIG. 2 along the axis 116 of rotation of the drum 114. In this case, there is an obtuse angle between a surface of the first support portion 108a′ arranged to support a first portion 102a′ of the first target 102 and a surface of the second support portion 108a″ arranged to support a second portion 102a″ of the first target 102.

This arrangement may facilitate the deposition of material of the first target 102 to form a first stripe on a first portion of the substrate 104. For example, with this arrangement, the material of the first target may be more compactly arranged within a region overlapped by the first portion of the substrate, during conveyance of the substrate 104 by the conveyor system 110. This may therefore increase the density of the material of the first target 102 deposited on the first portion of the substrate 104 and reduce or otherwise limit deposition of the material of the first target 102 elsewhere on the substrate 104.

In this example, the sputter deposition apparatus 100 includes a first target magnetic element 126a associated with the first target 102a, a second target magnetic element 126b associated with the second target 102b and a third target magnetic element 126c associated with the third target 102c. In other cases, though, there may be more or fewer target magnetic elements than targets.

In this example, the first target support assembly (which in this case includes the first and second support portions 108a′, 108a″) comprises the first target magnetic element 126a. The first target magnetic element 126a may be located beneath the first target support assembly such that, in use, the first target 102a is between the first target magnetic element 126a and the plasma 120 generated by the plasma generation arrangement 106. For example, the first target support assembly may be arranged to support the first target 102a between the first target magnetic element 126a and the conveyor system 110. The target support assemblies 108 may also or alternatively be arranged to support the second target 102b between the second target magnetic element 126b and the conveyor system 110 and/or the third target 102c between the third target magnetic element 126c and the conveyor system 110. The first target magnetic element 126a of FIG. 3 forms part of the first target support assembly. In yet further cases, the first target magnetic element 126a may be a separate element and/or may be located in a different location relative to the first target support assembly.

The first target magnetic element 126a may be considered to provide per-target biasing, allowing the magnetic field associated with the first target to be controlled. The magnetic field provided by the first target magnetic element 126a may be used to confine the plasma 120 in a region adjacent to the first target 102 supported by the first target support assembly, for example. This is shown schematically in FIG. 3, in which the plasma 120 has a first portion 120a extending towards the first and second portions 102a′, 102a″ of the first target 102a.

By controlling the magnetic field associated with different targets, deposition of material of the different targets may in turn be controlled. For example, the sputter deposition apparatus 100 may include a controller arranged to control a first magnetic field provided by the first target magnetic element 126a to control sputter deposition of material of the first target 102a. The controller may alternatively or additionally be arranged to control a second magnetic field provided by the second target magnetic element 126b to control sputter deposition of material of the second target 102b. For example, one or more of the target magnetic elements 126a, 126b, 126c may be an electromagnet and may have a magnetic field strength which is controllable using a suitable controller. Such a controller may include a processor such as a microprocessor which is arranged to control the current through the electromagnet, which in turn controls the magnetic field strength provided by the electromagnet. References herein to control of a magnetic field may be considered to refer to control of any characteristic of the magnetic field, including the magnetic field strength.

In some cases, during conveying the substrate 104 through the sputter deposition zone 112, a first magnetic field associated with the first target 102a and a second magnetic field associated with the second target 102b may be generated, for example using the first target magnetic element 126a to generate the first magnetic field and using the second target magnetic element 126b to generate the second magnetic field. The first magnetic field may be different from the second magnetic field, for example in magnetic field strength or another characteristic such as direction of magnetic field lines. As explained above, control of the magnetic fields associated with the first and second targets 102a, 102b in this way may be used to control a quantity of material of the first and second targets 102a, 102b which is sputter deposited on the substrate 104. This improves the flexibility of the sputter deposition apparatus 100, and for example allows the relative quantities of different target materials deposited on the substrate 104 to be controlled in a straightforward manner A magnetic field may be considered to be associated with a target where the magnetic field is generated by a target magnetic element associated with the target, such as a target magnetic element that is closer to a particular target than other targets. The magnetic field lines of such a magnetic field may have a greater density in the vicinity of the target than in the vicinity of another target, for example, such that the magnetic field strength of the magnetic field is higher in the vicinity of the target than in the vicinity of the other target (which may be an adjacent or neighbouring target).

FIG. 2 shows the third portion 120c of the plasma in plan view; other portions of the plasma are omitted for clarity. Due to the third magnetic field provided by the third target magnetic element 126c beneath the third target support assembly, the third portion 120c of the plasma is substantially confined in an elongate form which extends along a length of the third target 102c supported by the third target support assembly. This facilitates sputtering of the third target 102c, and hence deposition of material of the third target 102c on the substrate 104. Hence, in examples such as FIGS. 1 to 4, in which a target is elongate along the conveyance direction D in which the substrate 104 is conveyed by the conveyor system 110, a portion of the plasma (such as the third portion 120c of the plasma) may be substantially confined such that the portion of the plasma is elongate along the conveyance direction D. The confining of the portion of the plasma may be performed by a confining arrangement, which may include target magnetic element(s) and/or confining magnetic element(s). In the example of FIGS. 1 to 4, the first, second and third portions 120a, 120b, 120c of plasma are each elongate along the conveyance direction D; the first and second portions 120a, 120b for example have a similar shape in plan view to the third portion 120c illustrated in FIG. 2. However, this is merely an example, and in other cases, the plasma or a portion thereof may be confined differently.

Regions of the sputter deposition zone 112 in which magnetic elements, such as target magnetic elements or confining magnetic elements, are absent generally have a lower magnetic field strength, for example with a lower density of magnetic field lines. This can reduce the confining effect in these regions, which can affect the form of the plasma. This can be seen in FIG. 2, in which the third portion 120c of the plasma spreads out, and for example has a greater width, in an outer region (where the third target magnetic field element is absent) than in a central region (where the third target magnetic field element is present). This causes the third portion 120c of the plasma to have a substantially dog-bone shape in plan view. A substantially dog-bone shape is for example a shape with an elongate central portion and two opposite end portions, either side of the elongate central portion, which are greater in width than a width of the elongate central portion. The shape of the plasma in general depends on the configuration of magnetic elements within and/or surrounding the sputter deposition zone 112 and may change over time, as the plasma is typically not static. Moreover, the magnetic field provided by magnetic elements may change over time, which may further alter a shape or other configuration of the plasma.

In FIGS. 1 to 4, the first, second and third target support assemblies are the same as each other. A description of one of the first, second and third target support assemblies should be taken to apply to any other one of the first, second and third target support assemblies. Similarly, the first, second and third target magnetic elements 126a, 126b, 126c are the same as each other in FIGS. 1 to 4. A description of one of the first, second and third target magnetic elements 126a, 126b, 126c should be taken to apply to any other one of the first, second and third target magnetic elements 126a, 126b, 126c. However, it is to be appreciated that, in other examples, at least one of the first, second and third target support assemblies may differ from the others and/or at least one of the first, second and third target magnetic elements 126a, 126b, 126c may differ from the others.

As can be seen in FIG. 1, the conveyor system 110 of the sputter deposition apparatus 100 is arranged to convey the substrate 104 from a first side of the sputter deposition zone 112 (the left side of the sputter deposition zone 112 shown in FIG. 1) to a second side of the sputter deposition zone 112 (the right side of the sputter deposition zone 112 shown in FIG. 1). In examples, the one or more target support assemblies 108 are arranged to support at least two targets with a respective gap therebetween which extends from the first side of the sputter deposition zone 112 to the second side of the sputter deposition zone 112. For example, the one or more target support assemblies 108 may comprise a first target support assembly arranged to support at least a first target 102a and a second target support assembly arranged to support at least a second target 102b, such that there is a gap between the first target support assembly and the second target support assembly which extends from the first side of the sputter deposition zone 112 to the second side of the sputter deposition zone 112. There may also be a gap 128 between the first target 102a and the second target 102b. The gap 128 for example corresponds to a region between the first target support assembly and the second target support assembly, by which the first target support assembly is separated from the second target support assembly. In some cases, target material may be absent in the gap 128. The gap 128 may also lack other, intervening, elements between the first target 102a and the second target 102b. This for example avoids deposition of other materials on a portion of the substrate 104 corresponding to the gap 128, as the substrate 104 is conveyed through the sputter deposition zone 112.

As the gap 128 extends from the first side of the sputter deposition zone 112 to the second side of the sputter deposition zone 112, which is for example opposite to the first side, a portion of the substrate 104 overlaps the gap 128 during movement of the substrate 104 through the sputter deposition zone 112. This portion of the substrate 104 for example does not overlap or otherwise cover the first or second targets 102a, 102b as the substrate 104 traverses the sputter deposition zone 112. Hence, this causes a corresponding gap in deposition to occur on this portion of the substrate 104.

This is shown more clearly in FIG. 4, which shows schematically a top view of the sputter deposition apparatus 100 of FIGS. 1 to 3, in use. As can be seen in FIG. 4, after passing through the sputter deposition zone 112, the substrate 104 has a first stripe 130 on a first portion of the substrate 104, a second stripe 132 on a second portion of the substrate 104, a third stripe 134 on a third portion of the substrate 104, a fourth stripe 136 on a fourth portion of the substrate 104 and a fifth stripe 138 on a fifth portion of the substrate 104. In this example, the first stripe 130 is a stripe of material of the first target 102a, the second stripe 132 is an exposed surface of the second portion of the substrate 104, the third stripe 134 is a stripe of material of the second target 102b, the fourth stripe 136 is an exposed surface of the third portion of the substrate 104 and the fifth stripe 138 is a stripe of material of the third target 102c. In this way, the sputter deposition apparatus 100 can be used to provide for sputter deposition of the target material 102 supported by the one or more target support assemblies 108 such that the first stripe 130 comprises a different density and/or a different composition of the target material than the second stripe 132.

In the example of FIGS. 1 to 4, the first stripe 130 has a different density of the target material than the second stripe 132. The first stripe 130 has a higher density of the target material (which in this case is the of the first target 102a) than the second stripe 132 in this case. The second stripe 132 may comprise a lower density of the material of the first target 102a and a lower density of the material of the second target 102b. For example, the second stripe 132 may be substantially free from material of the first target 102a and/or the second target 102b, e.g. such that target material (e.g. from the first target 102a and/or the second target 102b) is substantially absent from the second stripe 132. The second stripe 132 may be considered substantially free from a given material where the given material is not present within measurement tolerances, is present in negligible quantities, such as relatively small or insignificant quantities, or is present in sufficiently small quantities so as not to require further processing to remove before the substrate 104 can be used for its intended purpose. A stripe of material is for example an elongate or extended strip of material. A stripe may be smaller in width than in length and may therefore correspond to a band of material. Opposite edges of the stripe, taken along its length, may be approximately parallel to each other, although this need not be the case. For example, a long edge of a stripe of material may be somewhat uneven or otherwise non-uniform, for example including deviations rather than following a precisely straight line. The material may nevertheless be considered to correspond to a stripe where it is generally elongate in shape.

In the examples herein, the positioning of the target material relative to the substrate 104 as the substrate 104 is conveyed through the sputter deposition zone 112 by the conveyor system 110 causes a striped pattern to be provided on the substrate 104. This allows a pattern of at least two stripes to be provided on the substrate 104 during a single pass of the substrate 104 through the sputter deposition apparatus 100, without further processing. A patterned substrate 104 can therefore be produced more efficiently and straightforwardly than otherwise. Furthermore, wastage of target material may be reduced, as the target material is deposited on desired areas of the substrate 104 without being deposited on other areas (such as the second area of the substrate 104 corresponding to the second stripe 132). This therefore obviates the need to remove target material from the second area of the substrate 104, and the subsequent wastage of the removed target material.

In examples such as that of FIG. 4, the first, second and third stripes 130, 132, 134 may be generated by conveying the first portion of the substrate 104 within a first region which substantially overlaps the first target 102a, conveying the second portion of the substrate 104 within a second region which substantially overlaps the gap 128 between the first target 102a and the second target 102b, and conveying the third portion of the substrate 104 within a third region which substantially overlaps the second target 102b. A region may be considered to substantially overlap a target where the region overlaps the target, exactly or within measurement or manufacturing tolerances. In some cases, a region may be considered to substantially overlap a target where sputter deposition of material of the target causes the material of the target to be present within the region. For example, a footprint of the region may be larger than a surface of the target closest to the conveyor system 110 because material of the target may be spread out or otherwise dispersed during sputter deposition.

The target support assemblies 108 may be arranged to support the one or more targets without an intervening element between the one or more targets and the substrate 104 during conveyance of the substrate 104 through the sputter deposition zone 112 by the conveyor system 110. In this way, the target material 102 may be sputter deposited on the substrate 104 by the sputter deposition apparatus 100 without the use of a mask or other obstructive element such as a shutter or baffle. This may reduce wastage of the target material due to deposition on the mask. Furthermore, deposition may be performed in a continuous manner, or for a longer period of time before stopping than other approaches, for example batch processes using masks. The efficiency of deposition may therefore be improved. In other cases, at least one intervening element may be arranged between the target material 102 and the substrate 104 during processing of the substrate 104 by the sputter deposition apparatus 100. Nevertheless, there may be fewer intervening elements, such as fewer masks, than with other approaches. Post processing of the substrate 104 may also be reduced compared with other approaches. For example, the density of material deposited on areas of the substrate which are intended to remain uncoated may be lower than otherwise. Such material may be more easily or efficiently removed than in other cases in which the density of material deposited is higher.

In the example of FIGS. 1 to 4, the gap 128 is elongate along the conveyance direction D in which the conveyor system 110 is arranged to convey the substrate 104. This allows an elongate strip which includes less target material than other stripes, such as the second stripe 132, to be provided on the substrate 104 in a simple way.

Similarly, in examples such as this, the target support assemblies 108 may be arranged to support the first target 102a such that the first target 102a is elongate along the conveyance direction D. The target support assemblies 108 may additionally or alternatively be arranged to support the second target 102b such that the second target 102b is elongate along the conveyance direction D and/or the third target 102c such that the third target 102c is elongate along the conveyance direction D. This facilities the deposition of stripes on the substrate 104. Moreover, by using elongate targets, the uniformity of the material deposited within a given stripe may be improved.

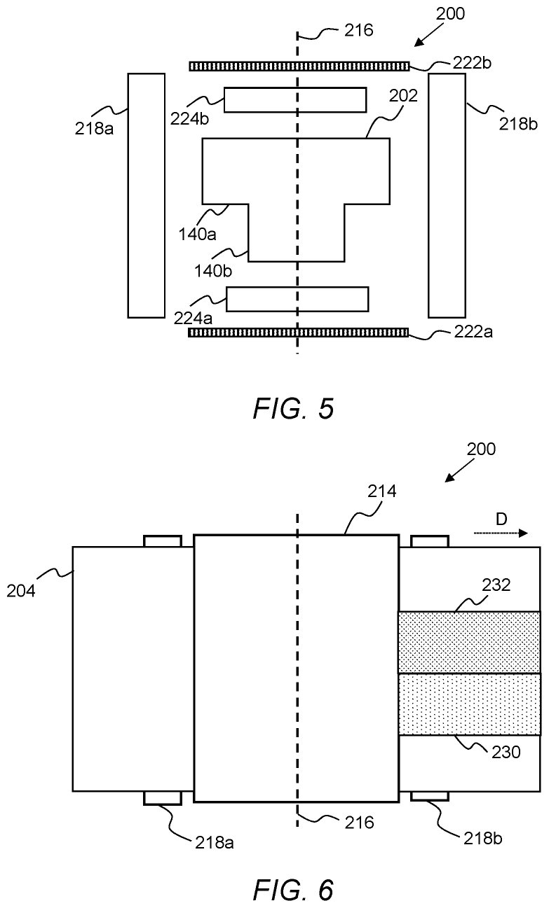

The principles behind the sputter deposition apparatus 100 of FIGS. 1 to 4 can be applied widely in the creation of various different patterns of material on a substrate 104. Other examples which utilise the principles behind the sputter deposition apparatus 100 of FIGS. 1 to 4 are illustrated in FIGS. 5 to 10.

FIGS. 5 and 6 show schematically respective portions of a sputter deposition apparatus 200 in plan view. The sputter deposition apparatus 200 of FIGS. 5 and 6 is the same as the sputter deposition apparatus 100 of FIGS. 1 to 4, except for the configuration of the target material 202, and the one or more target support assemblies for supporting the target material 202. FIG. 5 shows the sputter deposition apparatus 200 in the same view as the sputter deposition apparatus 100 shown in FIG. 2, and FIG. 6 shows the sputter deposition apparatus 200 in the same view as the sputter deposition apparatus 100 shown in FIG. 4. Features of FIGS. 5 and 6 which are similar to corresponding features of FIGS. 1 to 4 are labelled with the same reference numeral but incremented by 100; corresponding descriptions are to be taken to apply.

In the example of FIG. 5, a target support assembly is arranged to support a target 202 with a varying length along an axis substantially perpendicular to the conveyance direction D, such as along the axis 216 of rotation of the drum. In FIG. 5, the target 202 includes a first portion 140a with a first length at a first position along the axis 216 and a second portion 140b with a second length at a second position along the axis 216, which is different from the first length (and, in this case, is less than the first length). The first and second lengths may be taken along the conveyance direction D, for example in a direction substantially parallel to the conveyance direction D.

In this case, the target 202 is generally T-shape in plan view. However, in other examples, the target 202 may be of other shapes in plan view, which nevertheless vary in length along an axis substantially perpendicular to the conveyance direction D. The target support assembly may have any suitable shape or configuration to support the target 202. For example, the target support assembly in this case may also be generally T-shape in plan view, although other shapes are possible.

During use of the sputter deposition apparatus 200, a first portion of the substrate 204 may be conveyed within a first region which substantially overlaps the first portion 140a of the target 202 and a second portion of the substrate 204 may be conveyed within a second region which substantially overlaps the second portion 140b of the target. As the substrate 204 is conveyed in this manner, for example through the sputter deposition zone, sputter deposition of the material of the target 202 may be effected such that there is a first stripe 230 on the first portion of the substrate 204 and a second stripe 232 on the second portion of the substrate 204. The first stripe 230 comprises at least one of a different density of the material of the target 202 (which may be referred to as target material) or a different composition of the target material than the second stripe 232. In the present case, the second length of the second portion 140b is less than the first length of the first portion 140a of the target 202. A given portion of the substrate 204 therefore overlaps the second portion 140b of the target 202 for a shorter time period than the first portion 140a of the target 202 as the substrate 204 is conveyed through the sputter deposition apparatus 200. This causes a lower density of target material to be deposited on the second portion of the substrate 204 (which passes over the second portion 140b of the target 202) than on the first portion of the substrate 204 (which passes over the first portion 140a of the target 202).

The sputter deposition apparatus 200 of FIGS. 5 and 6 may be used to deposit two adjacent stripes of target material with different respective densities on the substrate 204 in an efficient manner, for example without the use of intervening elements such as masks.

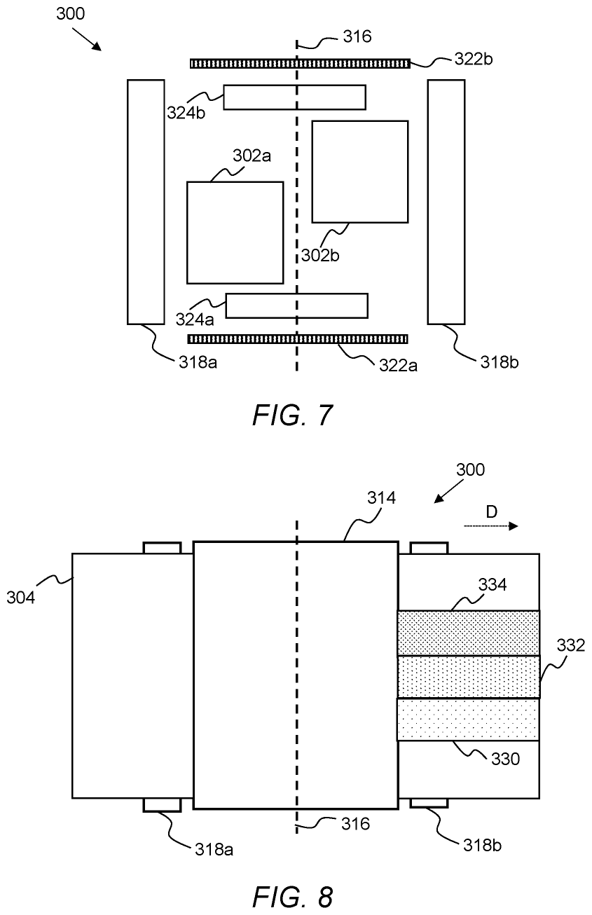

FIGS. 7 and 8 show schematically respective portions of a sputter deposition apparatus 300 in plan view. The sputter deposition apparatus 300 of FIGS. 7 and 8 is the same as the sputter deposition apparatus 100 of FIGS. 1 to 4, except for the configuration of the target material 302, and the one or more target support assemblies for supporting the target material 302. FIG. 7 shows the sputter deposition apparatus 300 in the same view as the sputter deposition apparatus 100 shown in FIG. 2, and FIG. 8 shows the sputter deposition apparatus 300 in the same view as the sputter deposition apparatus 100 shown in FIG. 4. Features of FIGS. 7 and 8 which are similar to corresponding features of FIGS. 1 to 4 are labelled with the same reference numeral but incremented by 200; corresponding descriptions are to be taken to apply.

In the example of FIGS. 7 and 8, the one or more target support assemblies are arranged to support a first target 302a and a second target 302b such that the second target 302b is offset from the first target 302a along an axis perpendicular to, but substantially within the plane of, the conveyance direction D, such as the axis 316 of rotation of the drum 314. With the first and second targets offset from each other in this way, there may be a gap between the first and second targets which extends from a first side of the sputter deposition zone to a second side of the sputter deposition zone (such as in the example of FIGS. 1 to 4), if the offset is large enough. However, in the example of FIGS. 7 and 8, an offset between the first and second targets 302a, 302b is insufficient for such a gap. An offset may for example be considered to be a displacement of the second target relative to the first target in a particular direction, such as along the axis perpendicular to the conveyance direction D. In FIGS. 7 and 8, the displacement, for example taken between an upper edge of the first target 302a and an upper edge of the second target 302b, in the sense of FIG. 7, is less than a width of the second target 302b along the axis 316. Due to this, there is a path from the first side of the sputter deposition zone to the second side of the sputter deposition zone which passes over or otherwise overlaps the second target 302b and then the first target 302a.

The target support assemblies may also or alternatively be arranged to support the first target 302a and the second target 302b such that the second target 302b is offset from the first target 302a along the conveyance direction D, e.g. along a second axis parallel to the conveyance direction D. This is the case in FIGS. 7 and 8: in this example, the first and second targets 302a, 302b are offset or otherwise displaced from each other both horizontally in the sense of FIG. 7 (i.e. along the conveyance direction D) and vertically in the sense of FIG. 7 (i.e. perpendicular to the conveyance direction D). This gives further flexibility for the deposition of stripes of material on the substrate 304, according to a desired pattern. The one or more target support assemblies may also be offset from each other along the conveyance direction D and/or perpendicular to the conveyance direction D.

Due to this arrangement of the first and second targets 302a, 302b, the substrate 304 may be conveyed by the conveyor system of the sputter deposition apparatus 300 to provide for sputter deposition of target material of the first and second targets 302a, 302b such that there is a first stripe 330 on a first portion of the substrate 304, a second stripe 332 on a second portion of the substrate 304 and a third stripe 334 on a third portion of the substrate 304. In this case, the first stripe 330 is a stripe of material of the first target 302a and the third stripe 334 is a stripe of material of the second target 302b. The material of the first target 302a differs from the material of the second target 302b in this example. The second stripe 332 is a combination of a material of the first target 302a and a material of the second target 302b. Hence, a composition of the second stripe 332 differs from a composition of the first stripe 330 in this case. The second stripe 332 may also comprise a different density of target material, such as a greater density of target material, than one or both of the first and third stripes 330, 334.

The second stripe 332 in this case is provided due to the position of the first and second targets 302a, 302b relative to the substrate 304 as the substrate 304 is conveyed through the sputter deposition apparatus 300. For example, the one or more target support assemblies may be arranged to support the first and second targets 302a, 302b such that, with the substrate 304 in a first position, the second portion of the substrate 304 (on which the second stripe 332 is provided) overlaps the first target 302a without overlapping the second target 302b and, with the substrate 304 in a second position, the second portion of the substrate 304 overlaps the second target 302b without overlapping the first target 302a. In this way, with the substrate 304 at the first position within the sputter deposition zone, deposition onto the second portion is due to the first target 302a and not the second target 30b. With the substrate 304 at the second position within the sputter deposition zone, deposition onto the second portion is due to the second target 302b and not the first target 302a. In this case, the substrate 304 is conveyed to the second position subsequently to the first position, as the substrate 304 is moved through the sputter deposition zone. This is merely an example, though. In other examples, the positions of the first and second targets 302a, 302b may be reversed compared with the positions shown in FIG. 7, for example with the second target 302b closer to the first side of the sputter deposition zone than the first target 302a.

By conveying the substrate 304 using the sputter deposition apparatus 300 of FIGS. 7 and 8, the second portion of the substrate 304 (on which the second stripe 332 is provided) may be conveyed within a first region of the sputter deposition zone which substantially overlaps the first target 302a. The same portion of the substrate 304 (in this case, the second portion, on which the second stripe 332 is provided) may be subsequently conveyed within a second region of the sputter deposition zone which substantially overlaps the second target 302b. In this way, a combination of material of both the first and second targets 302a, 302b may be deposited on the second portion of the substrate 304, to form the second stripe 332.

The combination of the material of the first target 302a and the material of the second target 302b of the second stripe 332 may be a mixture of materials of the first and second targets 302a, 302b. The sputter deposition apparatus 300 of FIGS. 7 and 8 therefore allows a mixed composition to be deposited straightforwardly and flexibly. In this case, a layer of the material of the first target 302a may be deposited on the substrate 304, and a layer of the material of the second target 302b may subsequently be deposited on the layer of the material of the first target 302a. In other cases, though, mixing of the material of the first and second targets 302a, 302b may occur within the sputter deposition zone, for example after the material has been ejected from the first and second targets 302a, 302b but before it has been deposited on the surface of the substrate 304.

In this example, the first and second targets 302a, 302b are generally rectangular in plan view, although this is merely an example and other shapes are possible. The one or more target support assemblies may have any suitable shape or configuration to support the first and second targets 302a, 302b.

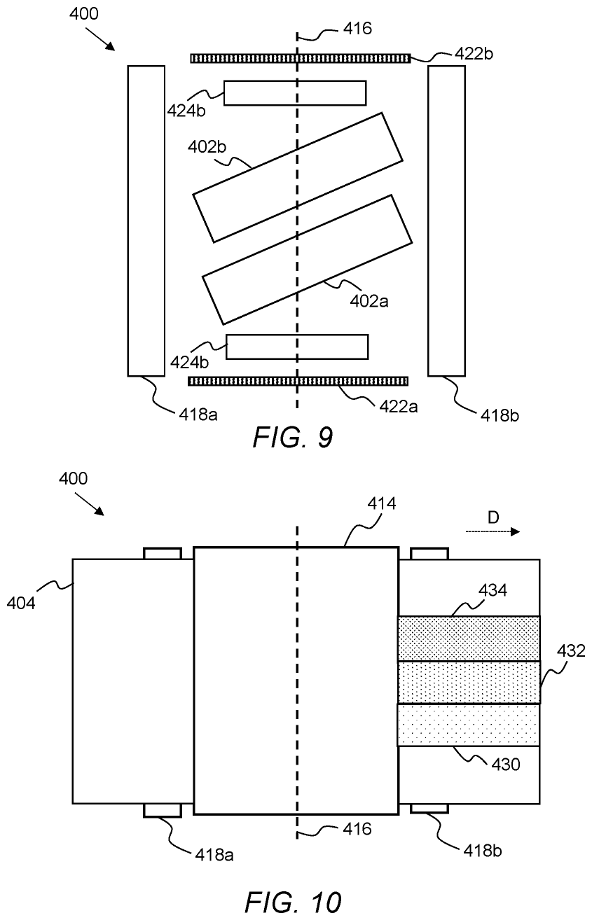

FIGS. 9 and 10 show schematically respective portions of a sputter deposition apparatus 400 in plan view. The sputter deposition apparatus 400 of FIGS. 9 and 10 is the same as the sputter deposition apparatus 100 of FIGS. 1 to 4, except for the configuration of the target material 402, and the one or more target support assemblies for supporting the target material 402. FIG. 9 shows the sputter deposition apparatus 400 in the same view as the sputter deposition apparatus 100 shown in FIG. 2, and FIG. 10 shows the sputter deposition apparatus 400 in the same view as the sputter deposition apparatus 100 shown in FIG. 4. Features of FIGS. 9 and 10 which are similar to corresponding features of FIGS. 1 to 4 are labelled with the same reference numeral but incremented by 100; corresponding descriptions are to be taken to apply.

The sputter deposition apparatus 400 of FIGS. 9 and 10 is similar to the sputter deposition apparatus 300 of FIGS. 7 and 8 in that it may be used to provide a first stripe 430 of material of a first target 402a on a first portion of a substrate 404, a second stripe 432 of a combination of material of the first target 402a and a second target 402b on a second portion of the substrate 404 and a third stripe 434 of material of the second target 402b on a third portion of the substrate 404. However, in examples such as that of FIGS. 9 and 10, the one or more target support assemblies are arranged to support the first target 402a and the second target 402b such that at least one of the first target 402a and the second target 402b are at an oblique angle with respect to the conveyance direction D. The one or more target support assemblies may themselves be at the oblique angle with respect to the conveyance direction D. The first and second target 402a, 402b may be at an oblique angle with respect to the conveyance direction D in a plane parallel to a plane of the surface of the substrate 404 as it is fed in to the sputter deposition apparatus 400, or in a plane which is parallel to a plane taken at a tangent to a surface of the first or second target 402a, 402b. For example, at least one of the first and second targets 402a, 402b may be at an oblique angle with respect to the conveyance direction D in plan view of the sputter deposition apparatus 400. An angle is considered oblique where it is for example less than 90 degrees. For example, the angle between at least one of the first and second targets 402a, 402b and the conveyance direction D may be more than 0 degrees and less than 90 degrees (within measurement tolerances).

By arranging the first and second targets 402a, 402b in this way, for example as shown in FIGS. 9 and 10, a portion of the substrate 404 (the second portion of the substrate 404 in this case) passes over or otherwise overlaps part of the second target 402b and, subsequently, part of the first target 402a as it is conveyed by the conveyor system. This causes a combination, such as a mixture, of material of the first and second targets 402a, 402b to be deposited as the second stripe 432 on the second portion of the substrate 404.

In the example of FIGS. 9 and 10, the first and second targets 402a, 402b are each elongate and rectangular in plan view. The first and second targets 402a, 402b are each at the same oblique angle with respect to the conveyance direction D in this case. However, this is merely an example and the first and second targets may have a different shape or position in other cases. For example, an angle between the first target 402a and the conveyance direction D may differ from an angle between the second target 402b and the conveyance direction D, for example to control a relative quantity of material of the first and second targets that is deposited as the second stripe 432. The one or more target support assemblies may have any suitable shape or configuration to support the first and second targets 402a, 402b.

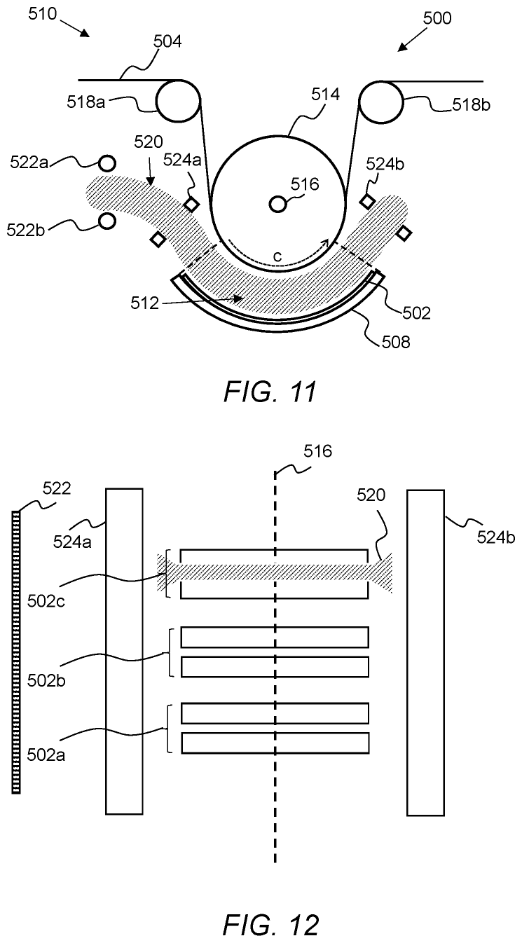

FIGS. 11 and 12 show schematically respective portions of a sputter deposition apparatus 500. The sputter deposition apparatus 500 of FIGS. 11 and 12 is the same as the sputter deposition apparatus 100 of FIGS. 1 to 4, except for the arrangement of the confining magnetic elements 524a, 524b and the antennae 522a, 522b. FIG. 11 shows the sputter deposition apparatus 500 in the same view as the sputter deposition apparatus 100 shown in FIG. 1, and FIG. 12 shows the sputter deposition apparatus 500 in the same view as the sputter deposition apparatus 100 shown in FIG. 2. However, in FIG. 12, the first and second rollers 518a, 518b are omitted, so the first and second confining magnetic elements 524a, 524b can be seen more clearly. Features of FIGS. 11 and 12 which are similar to corresponding features of FIGS. 1 to 4 are labelled with the same reference numeral but incremented by 400; corresponding descriptions are to be taken to apply.

In some cases, such as FIGS. 11 and 12, the sputter deposition apparatus 500 may include at least one confining magnetic element 524a, 524b which is elongate in a direction substantially perpendicular to the conveyance direction D, for example in a direction which is perpendicular to the conveyance direction D, perpendicular to the conveyance direction D within measurement tolerances or within a few degrees, such as within 5 degrees or 10 degrees. The confining magnetic elements 524a, 524b in such cases may be arranged such that a region of relatively high magnetic field strength provided between the confining magnetic elements 524a, 524b substantially follows the curve of the curved path C. In the example illustrated schematically in FIGS. 11 and 24, there are two confining magnetic elements 524a, 524b located on opposite sides of the drum 514 to one another, and each is disposed above a lowermost portion of the drum 514 (in the sense of FIG. 11). The confining magnetic elements 524a, 524b substantially confine the plasma 520 to follow the curve of the curved path C on both sides of the drum 514, for example a feed-on side where the web of substrate 504 is fed onto the drum 514, and a feed-off side in where the web of substrate 504 is fed off of the drum 514. Having at least two confining magnetic elements may therefore provide for a (further) increase in the area of the substrate 504 that is exposed to the plasma 520, and hence increased area in which sputter deposition may be effected. This may allow, for example, for the web of substrate 504 to be fed through a reel-to-reel type apparatus at a (still) faster rate for a given degree of deposition, and hence for more efficient sputter deposition. As for the confining magnetic elements 124a, 124b of FIGS. 1 to 4, one or more of the confining magnetic elements 524a, 524b of FIGS. 11 and 12 may be an electromagnetic, which may be controlled using a controller to control a strength of the magnetic field provided, to adjust a plasma density at the substrate 504. This may allow for improved flexibility in the operation of the sputter deposition apparatus 500.

In some examples, one or more of the confining magnetic elements 524a, 524b may be provided by a solenoid. Each solenoid may define an opening through which plasma 520 passes or is otherwise located in use. As per the example illustrated schematically in FIGS. 11 and 12, there may be two solenoids and each solenoid may be angled so that a region of relatively high magnetic field strength provided between the solenoids substantially follows the curve of the curved path C. In such a way, as illustrated in FIG. 1, the generated plasma 520 may pass through a first of the solenoids (such as the confining magnetic element 524a), under the drum 514 (in the sense of FIG. 11) into the sputter deposition zone 512, and up towards and through the second of the solenoids (such as the confining magnetic element 524b). For example, as illustrated in FIG. 12, one or more of the solenoids may be elongate in a direction substantially perpendicular to a direction of the magnetic field lines produced internally thereof in use, and may be elongate in a direction substantially perpendicular to a conveyance direction D in which the substrate 504 is conveyed by the conveyor system 510.

Although only two confining magnetic elements 524am 524b are shown in FIGS. 11 and 12, it will be appreciated that further confining magnetic elements (not shown), for example further such solenoids (not shown) may be placed along the curved path of the plasma 520. This may allow for strengthening of the confining magnetic field and hence for precise confinement and/or may allow for more degrees of freedom in the control of the confining magnetic field.

In examples such as that of FIGS. 11 and 12, the sputter deposition apparatus 500 may include one or more antennae 522a, 522b. The one or more antennae 522a, 522b may each be elongate antennae and extend in a direction substantially parallel to the longitudinal axis of the curved member (e.g. the axis 516 of rotation of the drum 514 which passes through the origin of the radius of curvature of the curved drum 514). At least one of the one or more antennae 522a, 522b may be linear or extend in an approximately straight, rather than curved, line. FIGS. 11 and 12 show such an example. At least one of the antennae (referred to collectively with the reference numeral 522) may extend along a length of the one or more target support assemblies 508. In FIGS. 11 and 12, the antennae 522 are longer in length than the one or more target support assemblies 508 along the axis 516 of rotation of the drum 514 to generate a plasma 520 which extends to cover the targets supported by the one or more target support assemblies 508. In other examples, though, the antennae 522 may be different in length to the one or more target support assemblies.

The above examples are to be understood as illustrative examples. Further examples are envisaged. For example, it is to be appreciated that features of any of these examples may be combined to create a more complex pattern of deposited material on a substrate. For example, by positioning targets in appropriate positions, using the one or more target support assemblies, relative to the conveyor system, the sputter deposition apparatus according to examples herein may be used to generate stripes of different material, combinations of material or lack of material, and/or stripes of various different sizes and/or separations.

FIGS. 1 to 4 and 11 and 12 illustrate two example antenna configurations. However, there may be various other antenna configurations (or other plasma generation arrangements) used to generate the plasma. For example, the antenna 122 illustrated in FIG. 1 has a curved shape, which may be considered to be an approximately half-moon shape. However, in other cases, a similar antenna may be used but with a circular rather than half-moon shape. In such cases, a circular antenna, for example with the same or a similar radius of curvature as the curved member, may be placed on each side of the drum, similar to the antennae 122a, 122b shown in FIG. 2 but with a different shape. In other cases, two antennae (such as two circular antennae) may be located on the same side of the drum or two antennae may be placed each side of the drum. In yet further cases, there may be a plurality of elongate antennae similar to the antenna 522 shown in FIG. 12. These elongate antennae may be placed at intervals, e.g. at regular intervals, around the curved member. In such cases, the elongate antennae may be spaced in a ladder-like fashion, between the one or more target support assemblies and the conveyor system, for example between the target(s) supported by the target support assemblies and the drum.

It is to be understood that any feature described in relation to any one example may be used alone, or in combination with other features described, and may also be used in combination with one or more features of any other of the examples, or any combination of any other of the examples. Furthermore, equivalents and modifications not described above may also be employed without departing from the scope of the accompanying claims.

1: A sputter deposition apparatus comprising:
a remote plasma generation arrangement arranged to provide a plasma for sputter deposition of target material within a sputter deposition zone;
a confining arrangement arranged to provide a confining magnetic field to substantially confine the plasma in the sputter deposition zone
a substrate provided within the sputter deposition zone; and
one or more target support assemblies arranged to support one or more targets in the sputter deposition zone so as to provide for sputter deposition of the target material on the substrate,
wherein the confining arrangement confines the remote plasma to the target support assemblies such that in use there is deposited:
target material as a first region on the substrate;
target material as a second region on the substrate; and
an intermediate region between the first and second region with no target material.

2: The sputter deposition apparatus according to claim 1, wherein:
a conveyor system is arranged to convey the substrate from a first side of the sputter deposition zone to a second side of the sputter deposition zone; and
the one or more target support assemblies comprise a first target support assembly arranged to support at least a first target and a second target support assembly arranged to support at least a second target,
wherein there is a gap between the first target support assembly and the second target assembly which extends from the first side of the sputter deposition zone to the second side of the sputter deposition zone.

3: The sputter deposition apparatus according to claim 2, wherein at least one of: the gap is elongate along the conveyance direction, the first target support assembly is elongate along the conveyance direction; or
the second target support assembly is elongate along the conveyance direction.

4: The sputter deposition apparatus according to claim 2, wherein:
the conveyor system is arranged to convey the substrate through the deposition zone from a first position thereof to a second position thereof; and
the one or more target support assemblies are arranged to support a first target and a second target such that, at the first position, deposition onto the second portion is due to the first target and not the second target and, at the second position, deposition onto the second portion is due to the second target and not the first target.

5: The sputter deposition apparatus according to claim 2, wherein the one or more target support assemblies are arranged to support a first target and a second target such that the second target is offset from the first target within the sputter deposition zone and along an axis perpendicular to, but substantially within the plane of, the conveyance direction.

6: The sputter deposition apparatus according to claim 5, wherein the axis is a first axis, and the one or more target support assemblies are arranged to support the first target and the second target such that the second target is offset from the first target within the sputter deposition zone and along the conveyance direction.

7: The sputter deposition apparatus according to claim 2, wherein the one or more target support assemblies are arranged to support the first target and the second target such that at least one of the first target and the second target are at an oblique angle with respect to the conveyance direction.

8: The sputter deposition apparatus according to claim 2, comprising a first target magnetic element associated with the first target and a second target magnetic element associated with the second target.

9: The sputter deposition apparatus according to claim 8, comprising a controller arranged to control at least one of:
a first magnetic field provided by the first target magnetic element to control sputter deposition of material of the first target; or
a second magnetic field provided by the second target magnetic element to control sputter deposition of material of the second target.

10: The sputter deposition apparatus according to claim 8, wherein the one or more target support assemblies are arranged to at least one of:
support the first target between the first target magnetic element and the conveyor system; or
support the second target between the second target magnetic element and the conveyor system.

11: The sputter deposition apparatus according to claim 2, wherein the material of the first target is different from the material of the second target.

12: The sputter deposition apparatus according to claim 2, the wherein the plasma generation apparatus comprises one or more elongate antennae, elongate along the conveyance direction.

13: The sputter deposition apparatus according to claim 12, wherein the conveyor system is arranged to convey the substrate along a curved path and the one or more elongate antennae are curved in the same direction as a curvature of the curved path.

14: The sputter deposition apparatus according to claim 2, comprising a confining arrangement arranged to provide a confining magnetic field to substantially confine plasma in the sputter deposition zone to provide for sputter deposition of the target material, wherein the confining arrangement comprises at least one confining magnetic element that is elongate along the conveyance direction.

15: The sputter deposition apparatus according to claim 14, wherein the confining arrangement comprises a further at least one confining magnetic element that is elongate in a direction substantially perpendicular to the conveyance direction.

16: The sputter deposition apparatus according to claim 2, wherein the one or more target support assemblies are arranged to support the one or more targets without an intervening element between the one or more targets and the substrate during conveyance of the substrate through the sputter deposition zone by the conveyor system.

17: The sputter deposition apparatus according to claim 2, wherein the conveyor system comprises a roller arranged to convey the substrate in the conveyance direction, wherein the conveyance direction is substantially perpendicular to an axis of rotation of the roller.

18: The sputter deposition apparatus according to claim 2, wherein the conveyor system comprises a curved member, and the one or more target support assemblies are arranged to support the one or more targets to substantially conform to a curvature of at least part of the curved member.

19: The sputter deposition apparatus according to claim 2, wherein a surface of at least one of the one or more targets facing the conveyor system is curved.

20: A method of sputter deposition of target material on a substrate, the method comprising:
providing plasma within a sputter deposition zone; and
conveying the substrate through the sputter deposition zone in a conveyance direction such that a position of one or more targets relative to the sputter deposition zone provides for sputter deposition of the target material on the substrate is such that, as the substrate is conveyed through the sputter deposition zone, there is deposited:
a first region on a first portion of the substrate;
a second region on a second portion of the substrate; and
an intermediate region between the first and second region with no target material,
wherein the first stripe comprises at least one of: a different density of the target material or a different composition of the target material than the second stripe.

21: The method according to claim 22, comprising sputter depositing a material of the first target as the first region on the first portion of the substrate and sputter depositing a material of the second target as a second region on the second portion of the substrate, wherein the second region at least one of:
comprises a lower density of the material of the first target than within the first stripe and a lower density of the material of the second target than within the third stripe; or
is substantially free from the material of the first target and the material of the second target.

22: The method according to claim 20, wherein conveying the substrate comprises:
conveying the first portion of the substrate within a first region of the sputter deposition zone which substantially overlaps a first portion of a target with a first length along the conveyance direction; and
conveying the second portion of the substrate within a second region of the sputter deposition zone which substantially overlaps a second portion of the target with a second length along the conveyance direction, wherein the first length is different from the second length.

23: The method according to claim 20, wherein conveying the substrate comprises:
conveying the second portion of the substrate within a first region of the sputter deposition zone which substantially overlaps a first target; and
subsequently, conveying the second portion of the substrate within a second region of the sputter deposition zone which substantially overlaps a second target.

24: The method according to claim 20, wherein the first target is elongate along the conveyance direction, and the method comprises substantially confining a portion of the plasma such that the portion of the plasma is elongate along the conveyance direction.

25: The method according to claim 20, comprising, during conveying the substrate, generating a first magnetic field associated with the first target and a second magnetic field associated with the second target, wherein the first magnetic field is different from the second magnetic field.
